(19) United States
(12) Patent Application Publication
(10) Pub. No.: US 2009/0295430 A1
(43) Pub. Date: Dec. 3, 2009

(54) METHOD AND APPARATUS FOR SIMULTANEOUS PROCESSING OF MULTIPLE FUNCTIONS

(75) Inventors: Adrian Stoica, Pasadena, CA (US); Radu Andrei, Pasadena, CA (US)

Correspondence Address: SETH Z. KALSON;c/o CPA Global, P.O. BOX 52050, MINNEAPOLIS, MN, 55402, US

(73) Assignee: California Institute of Technology, Pasadena, CA (US)

(21) Appl. No.: 12/393,562

(22) Filed: Feb. 26, 2009

Related U.S. Application Data
(60) Provisional application No. 61/067,666, filed on Feb. 29, 2008.

(51) Int. Cl. H03K 19/082; G06F 17/50

(52) U.S. Cl. 326/105; 716/18

(57) ABSTRACT

A methodology for describing an input-output behavior of a multi-level logic gate to process simultaneously a multiplicity of independent Boolean logic functions, with each Boolean function processing signals carried on an individual, separate channel. An embodiment may simultaneously process the same data with the same function or with different functions, multiple data with the same function, or multiple data with different functions. In addition, multi-level logic signals (having more than two levels) may be processed, so that a higher communication bandwidth may be obtained without necessarily increasing the number of traces (wires). Other embodiments are described and claimed.

### PRIORITY CLAIM

This application claims the benefit of U.S. Provisional Application No. 61/067,666, filed 29 Feb. 2008.

### GOVERNMENT INTEREST

The invention claimed herein was made in the performance of work under a NASA contract, and is subject to the provisions of Public Law 96-517 (35 USC 202) in which the Contractor has elected to retain title.

### FIELD

The present invention relates to electronic logic gates.

### BACKGROUND

A substantial amount of research in electronic microsystems has focused on bringing more computing power to smaller devices. Traditional approaches to increase computing bandwidth has often focused on exploiting concurrency, such as by allocating increasingly more gates to specific tasks, or by performing instructions faster, such as operating gates at higher speeds. These traditional approaches are expected to have diminishing returns, and may bump up against technological barriers, such as for example limitations on power dissipation.

### BRIEF DESCRIPTION OF THE DRAWINGS

FIG. 1 illustrates the input-output relationship of a logic gate according to an embodiment.

FIG. 2 illustrates the input-output relationship of an (AND, OR) logic gate according to an embodiment.

FIG. 3 illustrates a methodology for constructing the input-output relationship of a logic gate according to an embodiment.

FIG. 4 illustrates the input-output relationship of an adder logic unit according to an embodiment.

### DESCRIPTION OF EMBODIMENTS

In the description that follows, the scope of the term “some embodiments” is not to be so limited as to mean more than one embodiment, but rather, the scope may include one embodiment, more than one embodiment, or perhaps all embodiments.

Embodiments increase functional density at the logic gate level by combining multiple functions within a single gate. Embodiments may process simultaneously a multiplicity of independent Boolean logic functions, with each Boolean function processing signals carried on an individual, separate channel. An embodiment may simultaneously process the same data with the same function or with different functions, multiple data with the same function, or multiple data with different functions. In addition, multi-level logic signals (having more than two levels) may be processed, so that a higher communication bandwidth may be obtained without necessarily increasing the number of traces (wires). Such an embodiment may be referred to as a simul-gate.

Embodiments may be described by their input-output behavior. The input signals, and the output signal, may each in general have more than two logic levels, or values. For example, an input or output signal may have logic levels in the set

$$\{ 0 , ( \frac{1}{3} ) v , ( \frac{2}{3} ) v , v \} ,$$

where v is some voltage scale. A correspondence between the binary symbols 0 and 1 and these logic voltage levels may be taken as:

$$00 ↔ 0 ; 01 ↔ ( \frac{1}{3} ) v ; 10 ↔ ( \frac{2}{3} ) v ; and 11 ↔ v .$$

Other embodiments may have more than four logic levels. It is not necessary that the number of logic levels in a set of logic levels be a power of two.

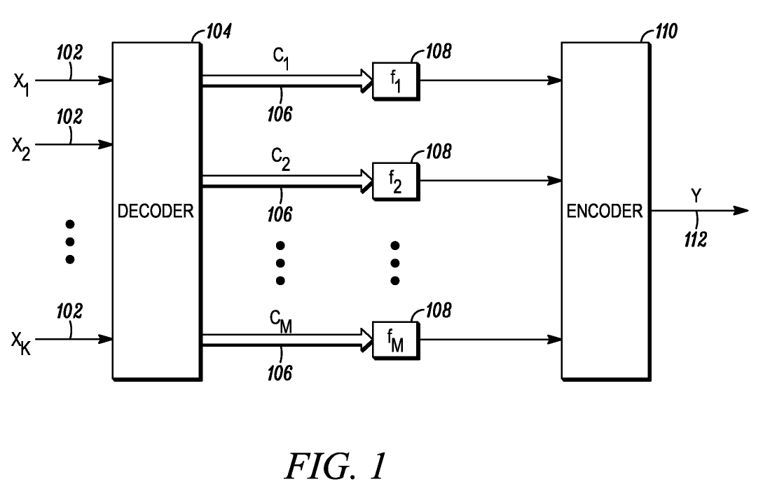

Referring to FIG. 1, the input-output behavior of an embodiment may be represented by K input ports 102, decoder 104, M channels 106, M Boolean gates 108, encoder 110, and output port 112. There are K input signals, one for each input port, denoted by xₖ, k=1, 2, . . . , K. The output signal at output port 112 is represented by y. The M Boolean functions fₘ, m=1, 2, . . . , M denote the functional behavior of the Boolean gates, where each fₘ denotes the functional input-output behavior of its corresponding Boolean gate. The M channels may be represented by the symbols Cₘ, m=1, 2, . . . , M. A channel Cm may be considered a set of input ports for the Boolean gate corresponding to the Boolean function fₘ.

In describing the input-output behavior of the embodiment in FIG. 1, each input signal xₖ is considered a multi-level logic signal, where decoder 104 decodes each multi-level logic signal into a set of binary signals. Each set of binary signals is dispersed among all the channels in the sense that for any particular set of binary signals, one binary signal from that set is provided to the first channel, a second binary signal from that set is provided to the second channel, and so on, so that the last binary signal from that set is provided to the last channel. For the particular embodiment illustrated in FIG. 1, each channel carries binary signals obtained from all the multi-level logic signals provided as input to decoder 104. However, other embodiments may have one or more channels that do not carry any binary signals associated with one or more input multi-level logic signals. Each channel may be viewed as carrying binary signals to its corresponding Boolean gate, where each Boolean gate then processes its binary signals to provide a binary output to encoder 110. Encoder 110 then encodes these binary signals to provide a multi-level logic signal at output port 112.

Embodiments may be described in more detail by introducing additional notation. Decoder 104 maps input signal xₖ into the M-tuple of bits (xₖ (M), xₖ (M−1), . . . , xₖ (2), xₖ (1)) for each k=1, 2, . . . , K, where each xₖ (m) is a binary logic signal, and where xₖ (m) is sent over channel Cₘ for each m=1, 2, . . . , M and for each k. In this way, for each m=1, 2, . . . , M, channel Cₘ carries the set of binary signals {x₁ (m), x₂ (m), . . . , x_{K} (m)}. For each m=1, 2, . . . , M, Boolean gate fm operates on the set of binary signals {x₁ (m) x₂ (m) . . . , x_{K} (m)} to provide an output binary signal that may be expressed as fₘ {x₁ (m), x₂ (m), . . . , x_{K} (m)}. This output binary signal may be written more compactly as fₘ {Cₘ}, where when Cₘ is the argument of fₘ, it stands for the set of binary signals carried on channel Cₘ. Encoder 112 has as its input the M-tuple of binary signals (f_{M} {C_{M}}, f_{M-1}{C_{M-1}}, . . . , f₂ {C₂}, f₁ {C₁}), and maps this into a multi-level logic output signal y.

For some embodiments, the output of each Boolean gate does not depend upon the ordering of its input signals. This was the motivation for using set notation in describing the input and output relationship of a Boolean gate. For example, the output binary signal of Boolean gate fₘ was written as fₘ {Cₘ}. For some embodiments, the decoding scheme is separable in the sense that the same decoding scheme is applied separately to each xₖ. If each Boolean gate does not depend upon the ordering of its input signals, and if the decoding scheme is separable so that the same decoding scheme is applied to each xₖ, then because each channel Cₘ carries the set of binary signals {x₁ (m), x₂ (m), . . . , x_{K} (m)} for each m=1, 2, . . . , M, the output of the simul-gate is independent of the ordering of the input signals xₖ.

For some embodiments the output of encoder 110 depends upon the ordering of its input signals. This was the motivation for using M-tuple notation for the encoder. As a result, for some embodiments the output signal y may depend upon the ordering of the correspondence between the Boolean gates and the channels. With this in mind, the input-output behavior for the embodiment of FIG. 1 may be referred to as an (f_{M}, f_{M-1}, . . . , f₂, f₁) simul-gate, where the use of an M-tuple reminds one that the input-output behavior may depend upon the ordering of the correspondence between the Boolean gates and the channels.

For some embodiments, the signals xₖ for k=1, 2, . . . , K may be such that a decoder maps input signal xₖ into the M′-tuple of bits (xₖ (M′), xₖ (M′−1), . . . , xₖ (2), xₖ (1)) for each k=1, 2, . . . , K, where each xₖ (m) is a binary logic signal, but where M′≠M. For example, if M′>M, then not all of the binary signals may be carried by the channels. As another example, if M′<M, then some channels may carry the same set of binary signals, but to different logic gates. In general, a subset of the set of K M′-tuples {(xₖ (M′), xₖ (M′−1), . . . , xₖ (2), xₖ (1)), k=1, 2, . . . , K} is transmitted over the M channels. A subset may not be a proper subset. That is, a subset of a set may be the set itself.

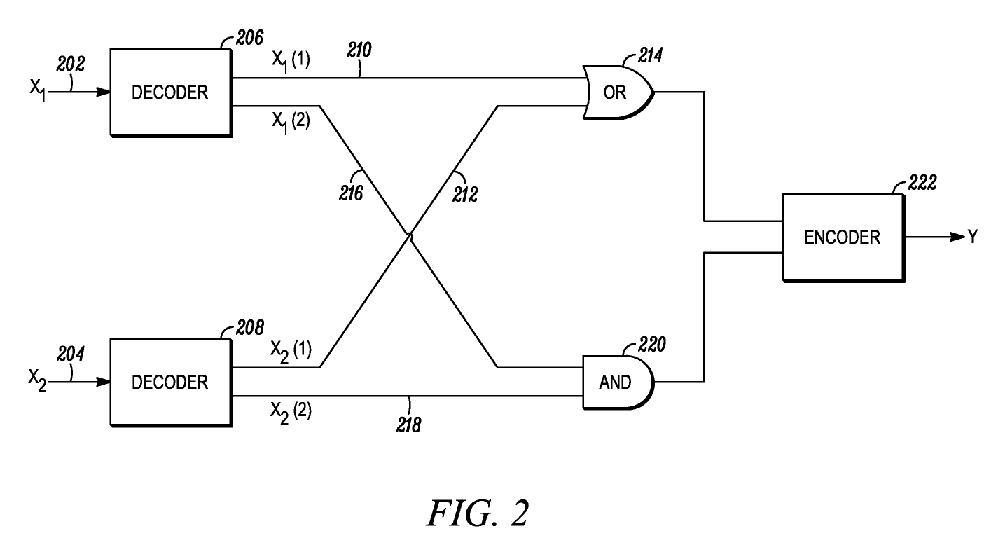

To provide a specific example of a simul-gate, an (AND, OR) simul-gate embodiment is illustrated in FIG. 2. The (AND, OR) simul-gate has two input ports: port 202 for input signal x₁ and port 204 for input signal x₂ Input signals x₁ and x₂ are each four-level logic signals, described by the set of voltage levels

$$\{ 0 , ( \frac{1}{3} ) v , ( \frac{2}{3} ) v , v \} ,$$

or for simplicity,

$$\{ 0 , ( \frac{1}{3} ) , ( \frac{2}{3} ) , 1 \}$$

where v is taken as unity. The decoding scheme is separable, where decoder 206 decodes input signal x₁, decoder 208 decodes input signal x₂, and decoders 206 and 208 each perform the identical decoding function

$$0 -> 00 ; ( \frac{1}{3} ) -> 01 ; ( \frac{2}{3} ) -> 10 ; and 1 -> 11.$$

Associated with channel C₁, denoted by data flows 210 and 212, is the Boolean OR function, represented by OR gate 214. Associated with channel C₂, denoted by data flows 216 and 218, is the Boolean AND function, represented by AND gate 220. Encoder 222 performs the inverse of decoders 206 and 208. That is,

$$00 -> 0 ; 01 -> ( \frac{1}{3} ) ; 10 -> ( \frac{2}{3} ) ; and 11 -> 1 ,$$

where the lowest and highest order bits in 00, 01, 10, and 11 refer to, respectively, the outputs of OR gate 214 and AND gate 220.

With the decoding and encoding schemes so defined, it is straightforward to develop the truth table for the (AND, OR) simul-gate of FIG. 2. For example, for x₁=⅔ and x₂=⅓, the output is y=⅓. Note that for an (OR, AND) simul-gate, OR gate 214 and AND gate 220 would exchange places in the topology of FIG. 2, so that an AND gate would be associated with channel C₁, and an OR gate would be associated with C₂. The truth table for the (OR, AND) gate is different from the truth table for the (AND, OR) gate.

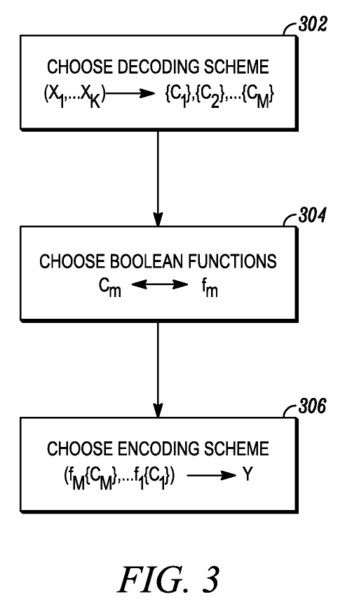

The data flows and logic gates in FIG. 1 illustrate the input-output behavior of a simul-gate, but do not necessarily represent a hardware description of an embodiment. FIG. 1 and its description provide a methodology for describing simulgates and constructing their input-output relationships based upon well known Boolean functions. FIG. 3 summarizes this method, where in block 302 a decoding scheme is chosen to decode K input multi-level logic signals into a set of M bits on each channel of M channels; in block 304 Boolean functions are chosen for each channel; and in block 306 an encoding scheme is chosen for encoding the output of the Boolean functions into the output signal.

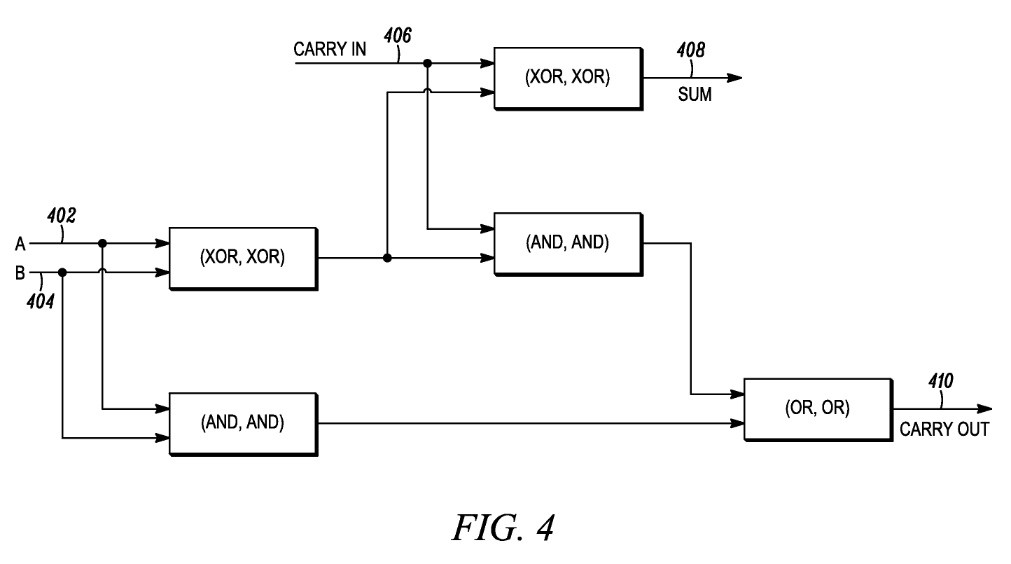

The methodology described herein may also be used to provide embodiments to increase the number of bits that are processed in a conventional system of conventional logic gates by replacing the conventional gates with simul-gates that perform the same function but on multiple channels. A particular example is illustrated in FIG. 4, where the methodology described herein was applied to a conventional one bit full adder logic unit. In this example, where the conventional full bit adder logic unit has a logic OR, AND, or XOR (exclusive OR) gate, that gate is replaced with, respectively, an (OR, OR), (AND, AND), or (XOR, XOR) simul-gate.

In FIG. 4, input signals “A” and “B” at input ports 402 and 404, and input signal “CARRY IN” at input port 406, are multi-level logic signals; and output signal “SUM” at output port 408 and output signal “CARRY OUT” at output port 410 are also multi-level logic signals. These signal names are derived from the conventional signal names in a conventional adder, where “A” and “B” represent the bits to be added along with the “CARRY IN” bits, and “SUM” represents the resulting sums where “CARRY OUT” are the bits to be carried over into the next adder unit. The encoding and decoding scheme as described with respect to the embodiment of FIG. 2 may be used with the simul-gates in the embodiment of FIG. 4. In this way, the embodiment of FIG. 4 processes two bits at a time.

For some embodiments, because the CARRY OUT signal isn't available for higher order bits until the lower order bits have been added, parts of the numbers to be added by an adder with simul-gates are time shifted so that the CARRY OUT signal is available when needed. The following example makes this clear. Suppose the numbers U and V are to be added, the numbers W and X are to be added, and the numbers Y and Z are to be added. Let the first and second bits of U be denoted as U[1] and U[2], respectively. Similar notation applies to the other numbers. Then for the first addition cycle, only one half of the adder is adding the two one-bit numbers U[1] and V[1]. At the second addition cycle, W[1] and X[1] are being added while at the same time U[2] and V[2] are being added. Because the part of the CARRY OUT signal associated with U[1] and V[1] is available at the beginning of the second addition cycle, it may be used in the CARRY IN signal for adding U[2] and V[2]. At the third addition cycle, Y[1] and Z[1] are being added, and W[2] and X[2] are being added. Because the part of the CARRY OUT signal associated with W[1] and X[1] is available at the beginning of the third addition cycle, it may be used in the CARRY IN signal for adding W[2] and X[2]. At the fourth addition cycle, only one half of the adder is adding the two one-bit numbers Y[2] and Z[2], and the part of the CARRY OUT signal associated with Y[1 ] and Z[1 ] is available to be used in the CARRY IN signal for adding Y[2] and Z[2].

In general, once a logic circuit has been specified comprising a set of N Boolean logic gates {Bᵢ, i=1, 2, . . . , N}, along with their interconnections, then a logic circuit comprising simul-gates may synthesized in which each logic gate Bᵢ is replaced with the simul-gate (Bᵢ, Bᵢ, . . . , Bᵢ), where Bi is repeated M times.

The embodiments described here are applicable to sequential logic as well as to combinational logic. Various modifications may be made to the disclosed embodiments without departing from the scope of the invention as claimed below.

What is claimed is:

1. A method to provide an input-output relationship to process K input multi-level logic signals into an output signal, the method comprising:
choosing a decoding scheme to decode the K input multi-level logic signals into a set of M′ bits on each channel of M channels;
choosing Boolean functions for each channel; and
choosing an encoding scheme to encode the output of the Boolean functions into the output signal.

2. The method as set forth in claim 1, where M′=M.

3. The method as set forth in claim 1, wherein the decoding scheme applies the same decoding function to each of the K input multi-level logic signals.

4. A logic gate to provide an output signal y in response to K input signals xₖ, k=1, 2, . . . , K, the logic gate comprising M channels Cₘ, m=1, 2, . . . , M to propagate data signals to perform M Boolean functions fₘ, m=1, 2, . . . , M, where for each k=1, 2, . . . , K, input signal xₖ maps into an M′-tuple of bits (xₖ (M′), xₖ (M′−1), . . . , xₖ (²), xₖ (1)), where each xₖ (m) is a binary logic signal, where a subset of the set of K M′-tuples {(xₖ (M′), xₖ (M′−1) . . . , xₖ (²), xₖ (1)), k=1, 2, . . . , K} is transmitted over the M channels, and where the output signal y is a function of the M-tuple of binary signals (f_{M} {C_{M}}, f_{M-1} {C_{M-1}}, . . . f₂ {C₂}, f₁ {C₁}), where for each m=1, 2, . . . , M, {Cₘ} is the subset of the set of K M′-tuples {(xₖ (M′), xₖ (M′−1), . . . , xₖ (2), xₖ (1)), k=1, 2, . . . , K} that is transmitted over the channel Cₘ, and fₘ {Cₘ} is an output of Boolean function fₘ for the set of binary logic signals {Cₘ}.

5. The logic gate as set forth in claim 4, where M′=M, where for each k=1, 2, . . . , K, xₖ (m) is sent over channel Cₘ for each m=1, 2, . . . , M, where for each m=1, 2, . . . , M, {Cₘ} is the set of binary logic signals {x₁ (m), x₂ (m), . . . , x_{K} (m)}.

6. The logic gate as set forth in claim 4, wherein a same mapping is applied to each signal xₖ.

7 . A method to synthesize a simul-gate logic circuit given a logic circuit comprising a set of Boolean logic gates {Bᵢ, i=1, 2, . . . , N}, the method comprising:
replacing, for each i=1, 2, . . . , N, the Boolean logic gate Bᵢ in the logic circuit with the simul-gate (Bᵢ, Bᵢ, . . . , Bᵢ), where Bᵢ is repeated M times.

8. The method as set forth in claim 7, where for each i=1, 2, . . . , N, the simul-gate (Bᵢ, Bᵢ, . . . , Bᵢ) is such that in response to K (i) input signals xₖ (i), k=1, 2, . . . , K (i), the the simul-gate (Bᵢ, Bᵢ, . . . , Bᵢ) comprises M channels Cₘ (i), m=1, 2, . . . , M to propagate data signals to perform the Boolean function Bᵢ M times, where for each k=1, 2, . . . , K (i), input signal xₖ (i) maps into an M-tuple of bits (xₖ (i, M), xₖ (i, M−1), . . . , xₖ (i, 2), xₖ (i, 1)), where each xₖ (i, m) is a binary logic signal, where xₖ (i, m) is sent over channel Cₘ (i) for each m=1, 2, . . . , M, and where an output signal y (i) is a function of the M-tuple of binary signals
(Bᵢ {C_{M} (i)}), Bᵢ {C_{M-1} (i)}, . . . , Bᵢ {C₂ (i)}, Bᵢ {C₁ (i)}), where for each k=1, 2, . . . , K(i), xₖ (i, m) is sent over channel Cₘ (i) for each m=1, 2, . . . , M, where for each m=1, 2, . . . , M, {Cₘ (i)} is the set of binary logic signals {x₁ (i, m), x₂ (i, m), . . . , x_{K} (i, m)}, and Bᵢ {Cₘ (i)} is the output of Boolean function Bi for the set of binary logic signals {Cₘ (i)}.
